(19) United States
(12) Patent Application Publication
(10) Pub. No.: US 2020/0013584 A1
(43) Pub. Date: Jan. 9, 2020

(54) METHOD OF OBTAINING DOSE CORRECTION AMOUNT, CHARGED PARTICLE BEAM WRITING METHOD, AND CHARGED PARTICLE BEAM WRITING APPARATUS

(71) Applicant: NuFlare Technology, Inc., Yokohama-shi (JP)

(72) Inventors: Satoru HIROSE, Yokohama-shi (JP); Rieko NISHIMURA, Yokohama-shi (JP)

(73) Assignee: NuFlare Technology, Inc., Yokohama-shi (JP)

(21) Appl. No.: 16/458,371

(22) Filed: Jul. 1, 2019

(30) Foreign Application Priority Data
Jul. 6, 2018 (JP) 2018-129251

(51) Int. Cl. H01J 37/302; H01J 37/30; H01J 37/317

(52) U.S. Cl. CPC H01J 37/3026; H01J 37/3174; H01J 37/3007

(57) ABSTRACT

In one embodiment, a method of obtaining a dose correction amount, the method includes writing evaluation patterns by irradiating a substrate with a charged particle beam by multiple writing with different numbers of paths using a charged particle beam writing apparatus, measuring a size of each of the evaluation patterns, calculating a size variation rate per path from a size measurement result of the evaluation pattern corresponding to each of the numbers of paths, and calculating a dose variation rate per path based on the size variation rate per path and a dose latitude indicating a ratio of a pattern size variation amount to a dose variation of the charged particle beam.

### CROSS REFERENCE TO RELATED APPLICATION

This application is based upon and claims benefit of priority from the Japanese Patent Application No. 2018-129251, filed on Jul. 6, 2018, the entire contents of which are incorporated herein by reference.

### FIELD

The present invention relates to a method of obtaining dose correction amount, a charged particle beam writing method, and a charged particle beam writing apparatus.

### BACKGROUND

With an increase in the packing density of LSIs, the required linewidths of circuits included in semiconductor devices become finer year by year. To form a desired circuit pattern on a semiconductor device, a method is employed in which a high-precision original pattern (i.e., a mask, or also particularly called reticle, which is used in a stepper or a scanner) formed on quartz is transferred to a wafer in a reduced manner by using a reduced-projection exposure apparatus. The high-precision original pattern is written by using an electron-beam writing apparatus, in which a so-called electron-beam lithography technique is employed.

In an electron beam writing apparatus, writing is performed by deflecting an electron beam with a deflector. A digital analog converter (DAC) amplifier is used for deflection of the electron beam. The roles of beam deflection using a DAC amplifier include control of the shape and size of a beam shot, control of the shot position, and blanking of a beam. For instance, a beam is deflected using a blanking deflector, OFF and ON of the beam is switched based on whether or not the beam is blocked by an aperture, and an irradiation time is controlled.

The number of shots of an electron beam necessary for mask writing has increased in association with the development of optical lithography technology and a short wavelength technique using EUV. Meanwhile, in order to secure line width accuracy necessary for refinement of a beam, reduction in shot noise and edge roughness of a pattern is aimed by decreasing the sensitivity of a resist and increasing a dose. A writing time has increased along with an increase in the number of shots and the dose. Thus, aiming to reduce the writing time by increasing the current density is being discussed.

However, when an increased irradiation energy amount is attempted to be emitted in a short time with an electron beam having a higher density, there is a problem in that a phenomenon so-called resist heating occurs, in which a substrate temperature increases, the sensitivity of a resist changes, and line width accuracy deteriorates. In order to reduce the effect of resist heating, multiple writing is performed in which a necessary dose is divided over writing (exposure) of multiple times.

A DAC amplifier, which applies a voltage to a blanking deflector, has a slope at the rise or the fall of the voltage. Therefore, the actual irradiation time (effective irradiation time) may become shorter than a desired setting irradiation time. The shortage of the effective irradiation time with respect to the setting irradiation time is also called a shot time offset. Since the shot time offset is provided, there is a problem in multiple writing in that when the number of paths (multiplicity) is changed, the pattern size varies. For instance, (the total of) the shot time offset when the number of paths is 4 is four times the shot time offset when the number of paths is 1, and the effective irradiation time is different between when the number of paths is 4 and when the number of paths is 1, thus the size of a writing pattern varies.

### BRIEF DESCRIPTION OF THE DRAWINGS

FIG. 1 is a schematic diagram of a writing apparatus according to an embodiment of the present invention.

FIG. 2 is a conceptual diagram illustrating a main deflection area and a secondary deflection area.

FIG. 3A and FIG. 3B are graphs illustrating a shot time offset.

FIG. 4 is a flowchart illustrating a method of obtaining a dose correction amount according to the embodiment.

FIG. 5 is a diagram illustrating an example of an evaluation pattern.

FIG. 6 is a graph illustrating an example of a relationship between the number of paths and the size of a writing pattern.

### DETAILED DESCRIPTION

In one embodiment, a method of obtaining a dose correction amount, the method includes writing evaluation patterns by irradiating a substrate with a charged particle beam by multiple writing with different numbers of paths using a charged particle beam writing apparatus, measuring a size of each of the evaluation patterns, calculating a size variation rate per path from a size measurement result of the evaluation pattern corresponding to each of the numbers of paths, and calculating a dose variation rate per path based on the size variation rate per path and a dose latitude indicating a ratio of a pattern size variation amount to a dose variation of the charged particle beam.

An embodiment of the present invention will be described below on the basis of the drawings. In the present embodiment, a configuration using an electron beam as an example of a charged particle beam will be described. The charged particle beam is not limited to the electron beam. Another charged particle beam, such as an ion beam, may be used.

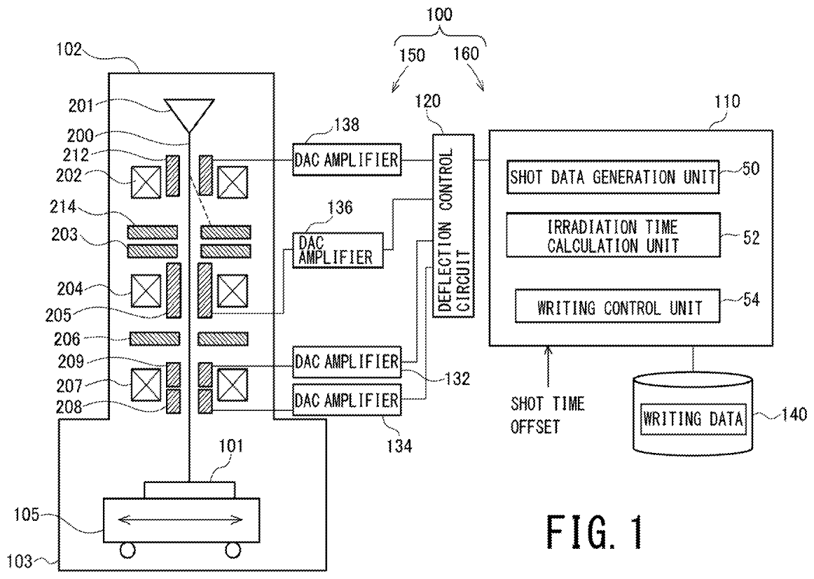

FIG. 1 is a schematic configuration diagram of a writing apparatus according to an embodiment of the present invention. As illustrated in FIG. 1, the writing apparatus 100 includes a writing unit 150 and a control unit 160. The writing apparatus 100 is an example of an electron beam writing apparatus. The writing unit 150 includes an electron beam column 102 and a writing chamber 103. In the electron beam column 102, an electron gun 201, an illumination lens 202, a blanking deflector (blanker) 212, a blanking aperture plate 214, a first shaping aperture plate 203, a projection lens 204, a shaping deflector 205, a second shaping aperture plate 206, an objective lens 207, a main deflector 208, and a sub-deflector 209 are disposed. A sub-sub-deflector may be further provided below the main deflector 208.

An XY stage 105 is disposed in the writing chamber 103 which is movable in at least XY directions. A substrate 101, which is a writing target, is placed on the XY stage 105. The substrate 101 includes a mask for exposure and a silicon wafer for manufacturing a semiconductor device. The mask includes mask blanks.

When an electron beam 200 irradiated from the electron gun 201 (an irradiator) passes through the blanking deflector 212, the electron beam 200 is controlled by the blanking deflector 212 so as to pass through the blanking aperture plate 214 in a beam ON state, and the entire beam is deflected so as to be blocked by the blanking aperture plate 214 in a beam OFF state. The electron beam 200, which passes through the blanking aperture plate 214 since a change to beam ON from a beam OFF state until beam OFF is subsequently achieved, provides a shot of the electron beam for one time.

The blanking deflector 212 controls the direction of the passing electron beam 200, and alternately generates a beam ON state and a beam OFF state. The dose per shot of the electron beam 200 radiated to the substrate 101 is adjusted by the irradiation time of each shot.

The electron beam 200 of each shot generated after passing through the blanking deflector 212 and the blanking aperture plate 214 illuminates the entire first shaping aperture plate 203 having a rectangular hole by the illumination lens 202. Here, the electron beam 200 is first shaped to a rectangle.

The electron beam 200 with an aperture image, which has passed through the first shaping aperture plate 203, is projected onto the second shaping aperture plate 206 by the projection lens 204. The aperture image on the second shaping aperture plate 206 is deflection-controlled by the shaping deflector 205, and the beam shape and the size can be changed. Such variable shaping is performed for each shot, and the electron beam 200 is normally shaped to a beam shape and a beam size which vary with shots.

The electron beam 200, which has passed through the second shaping aperture plate 206, is focused by the objective lens 207, deflected by the main deflector 208 and the sub-deflector 209, and is emitted to a desired position of the substrate 101 placed on the XY stage 105 which moves continuously. As described above, multiple shots of the electron beam 200 are sequentially deflected onto the substrate 101 by the deflectors.

FIG. 2 is a conceptual diagram illustrating a main deflection area and a secondary deflection area. As illustrated in FIG. 2, when a desired pattern is written by the writing apparatus 100, the writing area on the substrate 101 is divided into multiple stripe-shaped writing areas (stripes) 1 with a width by which each shot can be deflected, for instance, in the Y direction by the main deflector 208. Each stripe 1 is also divided in the X direction with the same width as the width of the stripe in the Y direction. The divided area is a main deflection area 2 by which each shot can be deflected by the main deflector 208. The main deflection area 2 is further subdivided into areas which are secondary deflection areas 3.

The sub-deflector 209 is used to control the position of the electron beam 200 for each shot with a high speed and high accuracy. For this reason, the deflection range is limited to the secondary deflection area 3, and deflection exceeding the area is performed by moving the position of the secondary deflection area 3 by the main deflector 208. In contrast, the main deflector 208 is used to control the position of the secondary deflection area 3, and the position is moved within a range (the main deflection area 2) including multiple secondary deflection areas 3. Since the XY stage 105 is continuously moved in the X direction during writing, movement of the XY stage 105 can be followed by moving (tracking) the writing origin of the secondary deflection area 3 as needed by the main deflector 208.

The control unit 160 has a control computer 110, a deflection control circuit 120, a digital-analog conversion (DAC) amplifier (units) 132, 134, 136, 138, and a storage device 140.

The control computer 110 includes a shot data generation unit 50 (a shot data generator), an irradiation time calculation unit 52 (an irradiation time calculator), and a writing control unit 54 (a writing controller). The functions of the shot data generation unit 50, the irradiation time calculation unit 52, and the writing control unit 54 may be configured by software or may be configured by hardware.

The deflection control circuit 120 is connected to the DAC amplifiers 132, 134, 136, and 138. The DAC amplifier 132 is connected to sub-deflector 209. The DAC amplifier 134 is connected to the main deflector 208. The DAC amplifier 136 is connected to the shaping deflector 205. The DAC amplifier 138 is connected to the blanking deflector 212.

A digital signal for blanking control is outputted from the deflection control circuit 120 to the DAC amplifier 138. The DAC amplifier 138 converts a digital signal to an analog signal, amplifies the signal, and applies the signal to the blanking deflector 212 as a deflection voltage. The electron beam 200 is deflected by the deflection voltage, and blanking control of each shot is performed.

A digital signal for shaping deflection is outputted from the deflection control circuit 120 to the DAC amplifier 136. The DAC amplifier 136 converts a digital signal to an analog signal, amplifies the signal, and applies the signal to the shaping deflector 205 as a deflection voltage. The electron beam 200 is deflected to a specific position of the second shaping aperture plate 206 by the deflection voltage, and an electron beam with desired shape and size is formed.

A digital signal for main deflection control is outputted from the deflection control circuit 120 to the DAC amplifier 134. The DAC amplifier 134 converts a digital signal to an analog signal, amplifies the signal, and applies the signal to the main deflector 208 as a deflection voltage. The electron beam 200 is deflected by the deflection voltage, and the beam of each shot is deflected to the writing origin of the secondary deflection area 3. When writing is performed while the XY stage 105 is continuously moved, the deflection voltage includes a deflection voltage for tracking, which follows stage movement.

A digital signal for secondary deflection control is outputted from the deflection control circuit 120 to the DAC amplifier 132. The DAC amplifier 132 converts a digital signal to an analog signal, amplifies the signal, and applies the signal to the sub-deflector 209 as a deflection voltage. The electron beam 200 is deflected to a shot position within the secondary deflection area 3 by the deflection voltage.

The storage device 140 is, for instance, a magnetic disk device, and stores writing data for writing a pattern on the substrate 101. The writing data is such that design data (layout data) is converted to a format for the writing apparatus 100, and the writing data is inputted from an external device, and is stored in the storage device 140.

The shot data generation unit 50 performs data conversion processing in multiple stages on the writing data stored in the storage device 140, divides each figure pattern, which is a writing target, into shot figures each having a size, which can be irradiated with a one-time shot, and generates shot data in a format specific to the writing apparatus. For each shot, the shot data includes, for instance, a figure code which indicates the figure type of each shot figure, a figure size, a shot position, and an irradiation time. The generated shot data is temporarily stored in a memory (illustration is omitted).

The irradiation time included in the shot data is calculated by the irradiation time calculation unit 52. The irradiation time calculation unit 52 calculates a dose (dose amount) Q of an electron beam at the position of each of the writing areas in consideration of factors which cause a size variation of a pattern, such as a proximity effect, a fogging effect, and a loading effect, and calculates an irradiation time by adding a shot time offset Ts to the time obtained by dividing the calculated dose Q by a current density and the number of paths (multiplicity) n of multiple writing.

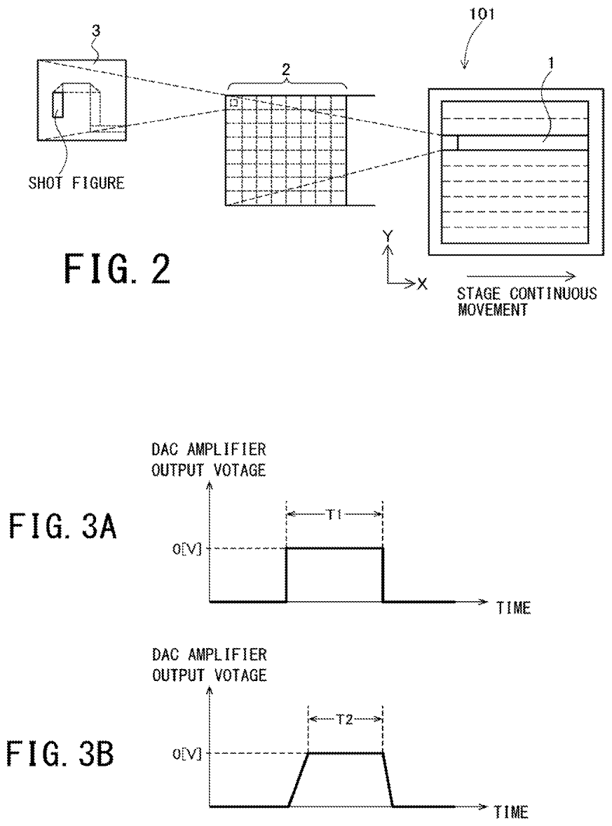

The shot time offset Ts will be described using FIGS. 3(a), 3(b). The irradiation time of an electron beam is controlled by ON/OFF switching of a beam performed by the blanking deflector 212. The blanking deflector 212 deflects the electron beam 200, and performs blanking control by a voltage applied by the DAC amplifier 138.

As illustrated in FIG. 3A, when the rise and the fall of an output voltage of the DAC amplifier 138 are vertical, a desired setting irradiation time T1 is obtained. However, actually, as illustrated in FIG. 3B, the DAC amplifier has a slope at the rise or the fall of the voltage. Therefore, the actual irradiation time (effective irradiation time) T2 is shorter than the desired setting irradiation time T1. The shortage of the effective irradiation time T2 with respect to the setting irradiation time T1 is the shot time offset Ts (=T1−T2).

In the embodiment, a substrate for evaluation as the substrate 101 is placed on the XY stage 105, an evaluation pattern described later is written, and the shot time offset Ts is calculated from a size measurement result of the written pattern. Then the calculated shot time offset Ts is inputted to the control computer 110 via an input unit (illustration is omitted).

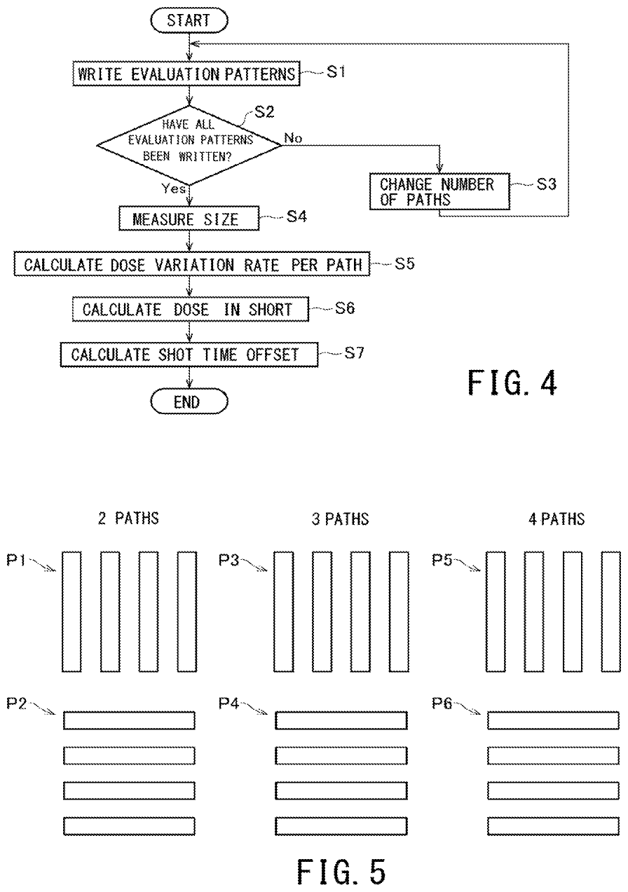

The method of obtaining the shot time offset Ts, which is a dose correction amount, will be described with reference to the flowchart illustrated in FIG. 4.

An evaluation pattern is written on the substrate 101 by changing the number of paths (multiplicity) using the writing apparatus 100 according to a multiple writing method (steps S1 to S3). The evaluation pattern is, for instance, a line and space pattern, or a contact hole pattern. For instance, as illustrated in FIG. 5, line and space patterns P1 to P6 are written in the x direction, the y direction by changing the number of paths to 2, 3, and 4. Let D be the dose when an evaluation pattern is written, then when the number of paths is 2, the dose per path is D/2, and when the number of paths is 3, the dose per path is D/3.

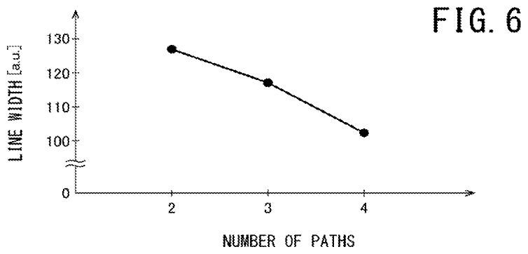

After an evaluation pattern is written (Yes in step S3), processing, such as developing, etching, is performed, and the size (line width) of the pattern formed is measured (step S4). The pattern size varies with the number of paths, and for instance, as illustrated in FIG. 6, the greater the number of paths is, the larger the shortage of the irradiation time is, and the smaller the size is.

It is to be noted that a substrate, an exposure device, and a developer device for writing an evaluation pattern are the same as those used when an actual product is manufactured.

A size variation rate per path Vcd is calculated from a size measurement result. A size variation rate (slope) per path is calculated, for instance, by the least square method from data at three points illustrated in FIG. 6. As shown in the following Expression 1, a dose variation rate per path Vd is calculated by dividing the size variation rate per path Vcd by dose Latitude (hereinafter denoted as DL) which has been determined beforehand (step S5).

Vd=Vcd/DL Expression 1:

The DL is a ratio of the amount of change in the line width (CD) to the amount of change in the dose, and for instance, is the amount of change in the line width when the dose amount is changed by 1%. The DL is calculated by writing a pattern having substantially the same pattern density as that of an evaluation pattern because the DL depends on the pattern density. The DL varies with the material quality, configuration of a resist and a light shielding film used for each site, and a difference in the mask process such as developing, etching. Thus, the shot time offset to be calculated can be more optimized by using the DL for calculation as in the embodiment.

Next, as shown in the following Expression 2, a dose Ds in short is calculated by multiplying the dose variation rate per path Vd by the dose D at the time of writing the evaluation pattern (step S6).

Ds=Vd·D Expression 2:

As shown in the following Expression 3, the shot time offset Ts is calculated by dividing the dose Ds in short by a current density J at the time of writing the evaluation pattern (step S7).

Ts=Ds/J Expression 3:

An average value of the shot time offset Ts calculated from a size measurement result of the line and space patterns P1, P3, P5 in the x direction, and the shot time offset Ts calculated from a size measurement result of the line and space patterns P2, P4, P6 in the y direction is inputted to the control computer 110. The irradiation time of each shot is calculated by adding the inputted shot time offset to the time obtained by dividing the dose of each path of multiple writing by a current density, and is registered in the shot data.

In a writing process, writing processing is performed using the shot data. The writing control unit 54 transfers the shot data to the deflection control circuit 120. The deflection control circuit 120 outputs deflection data (blanking signal), which is the irradiation time set in the shot data, to the DAC amplifier 138 for the blanking deflector 212.

The difference between the setting irradiation time T1 and the effective irradiation time T2 can be significantly reduced by setting the irradiation time in consideration of the shot time offset obtained by the technique according to the embodiment. Therefore, variation in the size of a writing pattern can be regulated by the number of paths of multiple writing.

In the embodiment described above, although an example has been explained in which an evaluation pattern is written with three types of the number of paths which is 2, 3, 4, in order to calculate the size variation rate per path Vcd, it is sufficient that an evaluation pattern be written by at least two types of the number of paths.

In the embodiment described above, although an example has been explained in which the shot time offset Ts calculated by an external device is inputted to the control computer 110, the dose variation rate per path Vd may be inputted to the control computer 110, and calculation of the dose Ds in short and the shot time offset Ts may be performed by the control computer 110 (the irradiation time calculation unit 52). The dose Ds in short may be inputted to the control computer 110, and calculation of the shot time offset Ts may be performed by the control computer 110.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method of obtaining a dose correction amount, the method comprising:
writing evaluation patterns by irradiating a substrate with a charged particle beam by multiple writing with different numbers of paths using a charged particle beam writing apparatus;
measuring a size of each of the evaluation patterns;
calculating a size variation rate per path from a size measurement result of the evaluation pattern corresponding to each of the numbers of paths; and
calculating a dose variation rate per path based on the size variation rate per path and a dose latitude indicating a ratio of a pattern size variation amount to a dose variation of the charged particle beam.

2. The method according to claim 1, further comprising:
calculating a dose in short based on the dose variation rate per path and a dose at a time of writing of the evaluation patterns; and
calculating a shot time offset which is shortage of an irradiation time of the charged particle beam, based on the dose in short and a current density of the charged particle beam at the time of writing of the evaluation patterns.

3. The method according to claim 2,
wherein the evaluation patterns include a first line and space pattern in a first direction and a second line and space pattern in a second direction perpendicular to the first direction, and
an average value of the shot time offset calculated using a size measurement result of the first line and sparse pattern, and the shot time offset calculated using a size measurement result of the second line and space pattern is calculated.

4. A charged particle beam writing method comprising:
irradiating a charged particle beam;
deflecting the charged particle beam using a blanking deflector, and performing blanking control so that one of beam ON and beam OFF states is achieved;
generating shot data from writing data, the shot data including a beam size and a shot position of each shot;
calculating an irradiation time of each shot by adding the shot time offset calculated by the method according to claim 2 to an irradiation time per path, the irradiation time per path being determined from a dose of the charged particle beam, a number of paths for multiple writing, and a current density; and
writing a pattern on a substrate by controlling the blanking deflector, a deflector that changes a beam shape and a beam size, and a deflector that adjusts a beam irradiation position based on the shot data including the calculated irradiation time.

5. The method according to claim 4,
wherein a stage on which the substrate is placed is controlled to move in a first direction,
the evaluation patterns include a first line and space pattern in the first direction and a second line and space pattern in a second direction perpendicular to the first direction, and
the shot time offset is obtained by averaging a first shot time offset calculated using a size measurement result of the first line and sparse pattern and a second shot time offset calculated using a size measurement result of the second line and space pattern.

6. A charged particle beam writing apparatus comprising:
an irradiator irradiating a charged particle beam;
a blanking deflector deflecting the charged particle beam, and performing blanking control so that one of beam ON and beam OFF states is achieved;
a shot data generator generating shot data from writing data, the shot data including a beam size and a shot position of each shot;
an inputter receiving an input of a dose variation rate per path, calculated by the method according to claim 1;
an irradiation time calculator calculating a dose in short based on the dose variation rate per path and a dose at a time of writing of the evaluation pattern, calculating a shot time offset which is shortage of an irradiation time of the charged particle beam, based on the dose in short and a current density of the charged particle beam at the time of writing of the evaluation pattern, and calculating an irradiation time of each shot by adding the shot time offset to an irradiation time per path, determined from a dose of the charged particle beam, a number of paths for multiple writing, and a current density; and
a deflection controller controlling the blanking deflector, a deflector that changes a beam shape and a beam size, and a deflector that adjusts a beam irradiation position based on the shot data including the calculated irradiation time.

7. The apparatus according to claim 6, further comprising a stage moving in a first direction on which the substrate is placed,
wherein the evaluation patterns include a first line and space pattern in the first direction and a second line and space pattern in a second direction perpendicular to the first direction, and
the shot time offset is obtained by averaging a first shot time offset calculated using a size measurement result of the first line and sparse pattern and a second shot time offset calculated using a size measurement result of the second line and space pattern.
